(19) United States
(12) Patent Application Publication
(10) Pub. No.: US 2026/0185214 A1
(43) Pub. Date: Jul. 2, 2026

(54) INTRAMOLECULAR STABILIZED GROUP 13 METAL COMPLEXES WITH IMPROVED THERMAL STABILITY FOR VAPOR PHASE THIN-FILM DEPOSITION TECHNIQUES

(71) Applicants: Merck Patent GMbH, Darmstadt (DE); Versum Materials US, LLC, Tempe, AZ (US)

(72) Inventors: Lukas Mai, Darmstadt (DE); Paul Mehlmann, Darmstadt (DE); Mark Marcello Maturi, Griesheim (DE); Holger Heil, Bad Vilbel (DE); Sergei Ivanov, Tamaqua, PA (US)

(21) Appl. No.: 19/130,079

(22) PCT Filed: Nov. 10, 2023
(86) PCT No.: PCT/US2023/079304

§ 371 Date: May 14, 2025

Related U.S. Application Data
(60) Provisional application No. 63/384,295, filed on Nov. 18, 2022.

(51) Int. Cl. C23C 16/18; C07F 5/02; C07F 5/06; C23C 10/06; C23C 16/455

(52) U.S. Cl. CPC C23C 16/18; C07F 5/02; C07F 5/06; C23C 10/06; C23C 16/45553

(57) ABSTRACT

The disclosed and claimed subject matter provides Group 13 (i.e., B, Al, Ga and In) compounds and methods of using the compounds as precursors for deposition of metal-containing films.

### BACKGROUND

### Field

The disclosed and claimed subject matter relates to Group 13 (i.e., B, Al, Ga and In) compounds and methods of using the compounds as precursors for deposition of metal-containing films.

### Related Art

Transition metal-containing films are used in semiconductor and electronics applications. Chemical Vapor Deposition (CVD) and Atomic Layer Deposition (ALD) have been applied as the main deposition techniques for producing thin films for semiconductor devices. These methods enable the achievement of conformal films (metal, metal oxide, metal nitride, metal silicide, and the like) through chemical reactions of metal-containing compounds (precursors). The chemical reactions occur on surfaces which may include metals, metal oxides, metal nitrides, metal silicides, and other surfaces. In CVD and ALD, the precursor molecule plays a critical role in achieving high quality films with high conformality and low impurities. The temperature of the substrate in CVD and ALD processes is an important consideration in selecting a precursor molecule. Higher substrate temperatures, in the range of 150 to 500 degrees Celsius (° C.), promote a higher film growth rate. The preferred precursor molecules must be stable in this temperature range. The preferred precursor is capable of being delivered to the reaction vessel in a liquid phase. Liquid phase delivery of precursors generally provides a more uniform delivery of the precursor to the reaction vessel than solid phase precursors.

In ALD, thin films can be deposited by the reaction of a metalorganic precursor with a co-reactant, separated by inert gas purges. Due to that unique mechanism ALD is able to coat three dimensional (3D) surfaces with an atomic precision which renders it indispensable for the semiconductor industry.

Precursors for ALD utilizing group 13 metal containing thin films are widely dominated by alkyl precursors, such as trimethyl indium, trimethyl gallium or trimethyl aluminum. These precursors have in common that they have a very high volatility and extreme reactivity enabling a huge variety of ALD processes for the respective metals, metal oxides, metal nitrides, metal sulfides and several inorganic-organic hybrid materials. However, the largest disadvantage is their high pyrophoricity which hampers the ease of their handling and renders them hazardous in case of accidents. Furthermore, the thermal stability is an issue in case of trimethyl indium which can only be used for deposition temperatures below 250° C.

Efforts to increase the thermal stability and to overcome the pyrophoric character of the trimethyl metal complexes resulted in the usage of an alkylaminoalkyl ligand, 3-(N,N-dimethylamino)propyl (DMP), which is bonded via its terminal carbon atom and a dative bond via the nitrogen atom to the electron deficient group 13 metal center in the complex. Thus, the chelating ligand can stabilize the complex by an electron donating function toward the metal.

Examples of such complexes are 3-(N,N-dimethylamino)propyl-dimethyl aluminum (DMAD) or 3-(N,N-dimethylamino)propyl-dimethyl indium (DADI). L. Mai et al., Chem-Eur. J, 23, 10768-10772 (2017) and L. Mai et al., Chem.-Eur. J, 25, 7489-7500 (2019) describe the synthesis of Al(DMP)R₂ with R=Me, NMe₂, NEt₂ and N(i-Pr)₂ and respective ALD processes with O₂ plasma or water. See also DE4213292. EP3256478 discloses the synthetic preparation of DADI. T. Hong et al., ACS Appl. Electron. Mater., 4, 3010-3017 (2022) describes a plasma enhanced ALD processes using DADI with oxygen. W. J. Maeng et al., Ceram. Int., 41, 10782-10787 (2015) and W. J. Maeng et al., J. Alloys Compd., 649, 216-221 (2015) describe ALD with DADI and water and with ozone, respectively. KR102043296 generally discloses a synthetic route to group 13 metal complexes with alkylaminoalkyle ligands having different substituents where each carbon of the alkyl chain must be substituted identically. WO2022190877A1 describes alkylaminoalkyl complexes with In and Zn as metal center but does not disclose a branched alkyl chain explicitly and hence no benefit of branched compared to linear alkyl chains can be expected or predicted. EP0690748, EP0260534 and U.S. Pat. No. 3,154,528 also disclose metal compounds with alkylaminoalkyl ligands, but only partly substituted alkyl chains with at least one hydrogen atom in β-position is disclosed as a branched alkyl chain.

Surprisingly, it was found that a modification of the chelate ligand could further improve/increase the thermal stability of the resulting metal complexes significantly. The β-position in the propyl chain relative to the was fully substituted with alkyl groups. Without being bound to theory, this substitution could potentially block precursor decomposition path by β-hydrogen elimination expected with other know precursors (e.g., those described in WO2022190877). Furthermore, by only substituting the β-position of the chain, an asymmetric character is introduced to the chain which lowers the melting point of the compounds and increase the volatility as compared to the heavier fully substituted systems such as those described in KR102043296.

### SUMMARY

The disclosed and claimed subject matter includes Group 13 (i.e., boron (B); aluminum (Al); gallium (Ga); and indium (In)) organometallic compounds and methods of using the compounds as precursors for deposition of metal-containing films. The disclosed and claimed subject matter further includes compositions containing the compounds, methods of using the compounds as precursors for deposition of metal-containing films and films derived from the precursors.

In one embodiment, the Group 13 compounds/precursors have Formula I:

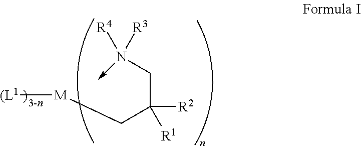

where
(a) R¹ and R² (i) are each independently one of a C₁-C₆ linear alkyl group, a C₃-C₆ branched alkyl group, and a C₃-C₆ cyclic alkyl group or (ii) are linked to form one of a 3-member ring, a 4-member ring, a 5-member ring and a 6-member ring;
(b) R³ and R⁴ are each independently one of a C₁-C₆ linear alkyl group, a C₃-C₆ branched alkyl group and a C₃-C₆ cyclic alkyl group;

$$n = 1 - 3 ; \qquad ( c )$$

(d) M is one of B, Al, Ga and In; and
(e) L¹ is one of a C₁-C₆ linear alkyl group, a C₃-C₆ branched alkyl group and an amino group of formula —NR⁵R⁶ where R⁵ and R⁶ are each independently one of a C₁-C₆ linear alkyl group and a C₃-C₆ branched alkyl group.

In one embodiment, the Group 13 compounds/precursors have Formula II:

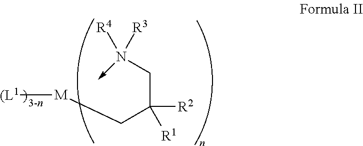

where
(a) R¹ and R² (i) are each independently one of a C₁-C₆ linear alkyl group, a C₃-C₆ branched alkyl group, and a C₃-C₆ cyclic alkyl group or (ii) are linked to form one of a 3-member ring, a 4-member ring, a 5-member ring and a 6-member ring;
(b) R³ and R⁴ are each independently one of a C₁-C₆ linear alkyl group, a C₃-C₆ branched alkyl group and a C₃-C₆ cyclic alkyl group;

$$n = 1 - 3 ; \qquad ( c )$$

(d) M is one of B, Al and Ga; and
(e) L¹ is one of a C₁-C₆ linear alkyl group, a C₃-C₆ branched alkyl group, and an amino group of formula —NR⁵R⁶ where R⁵ and R⁶ are each independently one of a C₁-C₆ linear alkyl group and a C₃-C₆ branched alkyl group.

In one embodiment, the Group 13 compounds/precursors have Formula III:

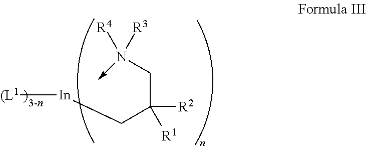

where
(a) R¹ and R² (i) are each independently one of a C₁-C₆ linear alkyl group, a C₃-C₆ branched alkyl group, and a C₃-C₆ cyclic alkyl group or (ii) are linked to form one of a 3-member ring, a 4-member ring, a 5-member ring and a 6-member ring;
(b) R³ and R⁴ are each independently one of a C₁-C₆ linear alkyl group, a C₃-C₆ branched alkyl group and a C₃-C₆ cyclic alkyl group;

$$n = 1 - 3 ; \qquad ( c )$$

(d) L¹ is one of a C₁-C₆ linear alkyl group, a C₃-C₆ branched alkyl group, and an amino group of formula —NR⁵R⁶ where R⁵ and R⁶ are each independently one of a C₁-C₆ linear alkyl group and a C₃-C₆ branched alkyl group.

The disclosed and claimed subject further includes (i) compositions and formulations that include the disclosed and claimed compounds and/or precursors, (ii) methods of using the disclosed and claimed compounds and/or precursors in deposition processes and (iii) metal-containing films derived from the disclosed and claimed compounds and/or precursors produced in deposition processes.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the ¹H NMR of the compound from Synthetic Example 1;

FIG. 2 illustrates the TGA of the compound from Synthetic Example 1;

FIG. 3 illustrates the differential scanning calorimetry analysis (DSC) of the compound from Synthetic Example 1;

FIG. 4 illustrates the ¹H NMR of the compound from Synthetic Example 2; and

FIG. 5 illustrates the TGA of the compound from Synthetic Example 2.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of.”

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

It will be understood that the term “silicon” as deposited as a material on a microelectronic device will include polysilicon.

For ease of reference, “microelectronic device” or “semiconductor device” corresponds to semiconductor wafers having integrated circuits, memory, and other electronic structures fabricated thereon, and flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” is not meant to be limiting in any way and includes any substrate that will eventually become a microelectronic device or microelectronic assembly.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

As used herein, “C_{x-y}” designates the number of carbon atoms in a chain. For example, C₁₋₆ alkyl refers to an alkyl chain having a chain of between 1 and 6 carbons (e.g., methyl, ethyl, propyl, butyl, pentyl and hexyl). Unless specifically stated otherwise, the chain can be linear or branched.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n- or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable example of mono-cyclic alkyl groups include substituted cyclopentyl, cyclohexyl, and cycloheptyl groups. The substituents may be any of the acyclic alkyl groups described herein. Suitable bicyclic alkyl groups include substituted bicyclo[2.2.1]heptane, bicyclo[2.2.2]octane, bicyclo[3.2.1]octane, bicyclo[3.2.2]nonane, and bicyclo[3.3.2]decane, and the like. Examples of tricyclic alkyl groups include tricyclo[5.4.0.0.^{2,9}]undecane, tricyclo[4.2.1.2.^{7,9}]undecane, tricyclo[5.3.2.0.^{4,9}]dodecane, and tricyclo[5.2.1.0.^{2,6}]decane. As mentioned herein the cyclic alkyl groups may have any of the acyclic alkyl groups as substituent. These alkyl moieties may be substituted or unsubstituted.

“Halogenated alkyl” refers to a linear, cyclic or branched saturated alkyl group as defined above in which one or more of the hydrogens has been replaced by a halogen (e.g., F, Cl, Br and I). Thus, for example, a fluorinated alkyl (a.k.a. “fluoroalkyl”) refers to a linear, cyclic or branched saturated alkyl group as defined above in which one or more of the hydrogens has been replaced by fluorine (e.g., trifluoromethyl, pefluoroethyl, 2,2,2-trifluoroethyl, prefluoroisopropyl, perfluorocyclohexyl and the like). Such haloalkyl moieties (e.g., fluoroalkyl moieties), if not perhalogenated/multihalogentated, may be unsubstituted or further substituted.

“Alkoxy” (a.k.a. “alkyloxy”) refers to an alkyl group as defined above which is attached through an oxy (—O—) moiety (e.g., methoxy, ethoxy, propoxy, butoxy, 1,2-isopropoxy, cyclopentyloxy, cyclohexyloxy and the like). These alkoxy moieties may be substituted or unsubstituted.

“Alkyl carbonyl” refers to an alkyl group as defined above which is attached through a carbonyl group (—C(═O—)) moiety (e.g., methylcarbonyl, ethylcarbonyl, propylcarbonyl, buttylcarbonyl, cyclopentylcarbonyl and the like). These alkyl carbonyl moieties may be substituted or unsubstituted.

“Halo” or “halide” refers to a halogen (e.g., F, Cl, Br and I).

“Hydroxy” or “hydroxyl” refers to an —OH group.

Unless otherwise indicated, the term “substituted” when referring to an alkyl, alkoxy, fluorinated alkyl and the like refers to one of these moieties which also contains one or more substituents including, but not limited, to the following substituents: alkyl, substituted alkyl, unsubstituted aryl, substituted aryl, alkyloxy, alkylaryl, haloalkyl, halide, hydroxy, amino and amino alkyl. Similarly, the term “unsubstituted” refers to these same moieties where no substituents apart from hydrogen are present.

Alkylene groups are divalent alkyl groups derived from any of the alkyl groups mentioned hereinabove. When referring to alkylene groups, these include an alkylene chain substituted with (C₁-C₁₈) alkyl groups in the main carbon chain of the alkylene group. Alkylene groups can also include one or more alkyne groups in the alkylene moiety, where alkyne refers to a triple bond. Essentially an alkylene is a divalent hydrocarbon group as the backbone. Accordingly, a divalent acyclic group may be methylene, 1,1- or 1,2-ethylene, 1,1-, 1,2-, or 1,3 propylene, 2,5-dimethyl-hexene, 2,5-dimethyl-hex-3-yne, and so on. Similarly, a divalent cyclic alkyl group may be 1,2- or 1,3-cyclopentylene, 1,2-, 1,3-, or 1,4-cyclohexylene, and the like. A divalent tricyclo alkyl groups may be any of the tricyclic alkyl groups mentioned herein above. An example of a tricyclic alkyl group is 4,8-bis(methylene)-tricyclo[5.2.1.0.^{2,6}]decane. When referring to a perfluoroalkylene these include materials describe above as alkylene group but in which the hydrogen atoms have been replaced by fluorine. Similarly, when describing a partially fluorinated alkylene group this is an alkylene group in which part of the hydrogen atoms have been replaced by fluorine.

Aryl groups contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents e.g., alkyl, alkoxy, acyl or aryl groups mentioned hereinabove. Similarly, appropriate polyvalent aryl groups as desired may be used in this invention. Representative examples of divalent aryl groups, arylene, include phenylenes, xylylenes, naphthylenes, biphenylenes, and the like. As used herein, and unless otherwise specified, the term “aromatic” refers to unsaturated cyclic hydrocarbons having a delocalized conjugated π system and having from 4 to 20 carbon atoms (aromatic C₄-C₂₀ hydrocarbon). Exemplary aromatics include, but are not limited to benzene, toluene, xylenes, mesitylene, ethylbenzenes, cumene, naphthalene, methylnaphthalene, dimethylnaphthalenes, ethylnaphthalenes, acenaphthalene, anthracene, phenanthrene, tetraphene, naphthacene, benzanthracenes, fluoranthrene, pyrene, chrysene, triphenylene, and the like, and combinations thereof. The aromatic may optionally be substituted, e.g., with one or more alkyl group, alkoxy group, halogen, etc. For example, the aromatic may include anisole. Additionally, the aromatic may include one or more heteroatoms. Examples of heteroatoms include, but are not limited to, nitrogen, oxygen, phosphorus, boron, and/or sulfur. Aromatics with one or more heteroatom include, but are not limited to furan, benzofuran, thiophene, benzothiophene, oxazole, thiazole and the like, and combinations thereof. The aromatic may comprise monocyclic, bicyclic, tricyclic, and/or polycyclic rings (in some embodiments, at least monocyclic rings, only monocyclic and bicyclic rings, or only monocyclic rings) and may be fused rings.

As used here, the term “arene” means cyclic hydrocarbons with alternating double and single bonds between carbon atoms (i.e., aromatic rings) and also includes heteroarenes where one or more carbon atoms forming such aromatic rings is replaced by a hetero atom (e.g., oxygen, sulfur, nitrogen, silicon, germarium, phosphorus). Examples of arenes include, for example, benzene, substituted benzene, naphthalene, anthracene and the like. Examples of heteroarenes include, for example, pyridine, furan, indole, benzimidazole, thiophene, benzthiazole and the like.

The term “non-aromatic” means four or more carbon atoms joined in at least one ring structure wherein at least one of the four or more carbon atoms in the ring structure is not an aromatic carbon atom.

“Substantially free” is defined herein as less than 0.001 wt. %. “Substantially free” also includes 0.000 wt. %. The term “free of” means 0.000 wt. %. As used herein, “about” or “approximately” are intended to correspond to within ±5% of the stated value.

In all such compositions, wherein specific components of the composition are discussed in reference to weight percentage (or “weight %”) ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all percentages of the components are weight percentages and are based on the total weight of the composition, that is, 100%. Any reference to “one or more” or “at least one” includes “two or more” and “three or more” and so on.

Where applicable, all weight percents unless otherwise indicated are “neat” meaning that they do not include the aqueous solution in which they are present when added to the composition. For example, “neat” refers to the weight % amount of an undiluted acid or other material (i.e., the inclusion 100 g of 85% phosphoric acid constitutes 85 g of the acid and 15 grams of diluent).

Moreover, when referring to the compositions described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the formulation can contain 2% by weight or less of impurities. In another embodiment, the formulation can contain 1% by weight or less than of impurities. In a further embodiment, the formulation can contain 0.05% by weight or less than of impurities. In other such embodiments, the constituents can form at least 90 wt %, more preferably at least 95 wt %, more preferably at least 99 wt %, more preferably at least 99.5 wt %, most preferably at least 99.9 wt %, and can include other ingredients that do not material affect the performance of the wet etchant. Otherwise, if no significant non-essential impurity component is present, it is understood that the composition of all essential constituent components will essentially add up to 100 weight %.

The headings employed herein are not intended to be limiting; rather, they are included for organizational purposes only.

### Exemplary Embodiments

One aspect of the disclosed and claimed subject matter pertains to Group 13 (i.e., B, Al, Ga and In) compounds and methods of using the compounds as precursors for deposition of metal-containing films.

In one embodiment, the Group 13 compounds/precursors have Formula I.

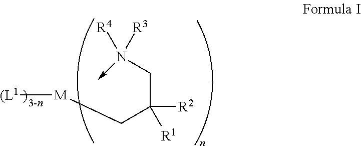

where
(a) R¹ and R² (i) are each independently one of a C₁-C₆ linear alkyl group, a C₃-C₆ branched alkyl group, and a C₃-C₆ cyclic alkyl group or (ii) are linked to form one of a 3-member ring, a 4-member ring, a 5-member ring and a 6-member ring;
(b) R³ and R⁴ are each independently one of a C₁-C₆ linear alkyl group, a C₃-C₆ branched alkyl group and a C₃-C₆ cyclic alkyl group;

$$n = 1 - 3 ; \qquad ( c )$$

(d) M is one of B, Al, Ga and In; and
(e) L¹ is one of a C₁-C₆ linear alkyl group, a C₃-C₆ branched alkyl group, and an amino group of formula —NR⁵R⁶ where R⁵ and R⁶ are each independently one of a C₁-C₆ linear alkyl group and a C₃-C₆ branched alkyl group.

In one aspect of this embodiment, M is B. In another aspect of this embodiment, M is Al. In another aspect of this embodiment, M is Ga. In another aspect of this embodiment, M is In.

In one aspect of this embodiment, n=1. In another aspect of this embodiment, n=2. In another aspect of this embodiment, n=3.

In one aspect of this embodiment, R¹ and R² are each independently one of a C₁-C₆ linear alkyl group, a C₃-C₆ branched alkyl group and a C₃-C₆ cyclic alkyl group. In one aspect of this embodiment, R³ and R⁴ are each independently one of a C₁-C₆ linear alkyl group, a C₃-C₆ branched alkyl group and a C₃-C₆ cyclic alkyl group. In one aspect of this embodiment, R¹, R², R³ and R⁴ are each independently one of a C₁-C₆ linear alkyl group, a C₃-C₆ branched alkyl group and a C₃-C₆ cyclic alkyl group.

In one aspect of this embodiment, R¹ and R² are linked to form one of a 3-member ring, a 4-member ring, a 5-member ring and a 6-member ring.

In one aspect of this embodiment, R¹ and R² are linked to form a 3-member ring. In one aspect of this embodiment, R¹ and R² are linked to form a cyclopropyl ring.

In one aspect of this embodiment, R¹ and R² are linked to form a 4-member ring. In one aspect of this embodiment, R¹ and R² are linked to form a cyclobutyl ring.

In one aspect of this embodiment, R¹ and R² are linked to form a 5-member ring. In one aspect of this embodiment, R¹ and R² are linked to form a cyclopentyl ring.

In one aspect of this embodiment, R¹ and R² are linked to form a 6-member ring. In one aspect of this embodiment, R¹ and R² are linked to form a cyclohexyl ring.

In one aspect of this embodiment, three or more of L¹, R¹, R², R³, R⁴, R⁵ and R⁶ are a methyl group (“Me” or “—CH₃”). In one aspect of this embodiment, two or more of L¹, R¹, R², R³, R⁴, R⁵ and R⁶ are a methyl group (“Me” or “—CH₃”). In one aspect of this embodiment, L¹, R¹, R², R³ and R⁴ are each a methyl group (“Me” or “—CH₃”). In one aspect of this embodiment, n=1 and L¹, R¹, R², R³ and R⁴ are each a methyl group (“Me” or “—CH₃”). In one aspect of this embodiment, n=2 and L, R¹, R², R³ and R⁴ are each a methyl group (“Me” or “—CH₃”). In one aspect of this embodiment, R⁵ and R⁶ are present and are each a methyl group (“Me” or “—CH₃”).

In one aspect of this embodiment, three of L¹, R¹, R², R³, R⁴, R⁵ and R⁶ are an ethyl group (“Et” or “—CH₂CH₃”). In one aspect of this embodiment, two of L¹, R¹, R², R³, R⁴, R⁵ and R⁶ are an ethyl group (“Et” or “—CH₂CH₃”). In one aspect of this embodiment, L¹, R¹, R², R³ and R⁴ are each an ethyl group (“Et” or “—CH₂CH₃”). In one aspect of this embodiment, n=1 and L¹, R¹, R², R³ and R⁴ are each an ethyl group (“Et” or “—CH₂CH₃”). In one aspect of this embodiment, n=2 and L¹, R¹, R², R³ and R⁴ are each an ethyl group (“Et” or “—CH₂CH₃”). In one aspect of this embodiment, R⁵ and R⁶ are present and are each an ethyl group (“Et” or “—CH₂CH₃”).

In one aspect of this embodiment, three or more of L¹, R¹, R², R³, R⁴, R⁵ and R⁶ are a propyl group (“Pr” or “—CH₂CH₂CH₃”). In one aspect of this embodiment, two or more of L¹, R¹, R², R³, R⁴, R⁵ and R⁶ are a propyl group (“Pr” or “—CH₂CH₂CH₃”). In one aspect of this embodiment, L¹, R¹, R², R³ and R⁴ are each a propyl group (“Pr” or “—CH₂CH₂CH₃”). In one aspect of this embodiment, n=1 and L, R¹, R², R³ and R⁴ are each a propyl group (“Pr” or “—CH₂CH₂CH₃”). In one aspect of this embodiment, n=2 and L¹, R¹, R², R³ and R⁴ are each a propyl group (“Pr” or “—CH₂CH₂CH₃”). In one aspect of this embodiment, R⁵ and R⁶ are present and are each a propyl group (“Pr” or “—CH₂CH₂CH₃”).

In one aspect of this embodiment, two or more of L¹, R¹, R², R³, R⁴, R⁵ and R⁶ are an isopropyl group (“iPr”). In one aspect of this embodiment, at least one of L¹, R¹, R², R³, R⁴, R⁵ and R⁶ is an isopropyl group (“iPr”).

In one embodiment, the Group 13 compounds/precursors have Formula II:

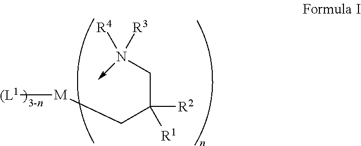

where
(a) R¹ and R² (i) are each independently one of a C₁-C₆ linear alkyl group, a C₃-C₆ branched alkyl group, and a C₃-C₆ cyclic alkyl group or (ii) are linked to form one of a 3-member ring, a 4-member ring, a 5-member ring and a 6-member ring;
(b) R³ and R⁴ are each independently one of a C₁-C₆ linear alkyl group, a C₁-C₆ branched alkyl group and a C₃-C₆ cyclic alkyl group;

$$n = 1 - 3 ; \qquad ( c )$$

(d) M is one of B, Al and Ga; and
(e) L¹ is one of a C₁-C₆ linear alkyl group, a C₃-C₆ branched alkyl group, and an amino group of formula —NR⁵R⁶ where R⁵ and R⁶ are each independently one of a C₁-C₆ linear alkyl group and a C₁-C₆ branched alkyl group.

In one aspect of this embodiment, M is B. In another aspect of this embodiment, M is Al. In another aspect of this embodiment, M is Ga.

In one aspect of this embodiment, n=1. In another aspect of this embodiment, n=2. In another aspect of this embodiment, n=3.

In one aspect of this embodiment, R¹ and R² are each independently one of a C₁-C₆ linear alkyl group, a C₃-C₆ branched alkyl group and a C₃-C₆ cyclic alkyl group. In one aspect of this embodiment, R³ and R⁴ are each independently one of a C₁-C₆ linear alkyl group, a C₃-C₆ branched alkyl group and a C₃-C₆ cyclic alkyl group. In one aspect of this embodiment, R¹, R², R³ and R⁴ are each independently one of a C₁-C₆ linear alkyl group, a C₃-C₆ branched alkyl group and a C₃-C₆ cyclic alkyl group.

In one aspect of this embodiment, R¹ and R² are linked to form one of a 3-member ring, a 4-member ring, a 5-member ring and a 6-member ring.

In one aspect of this embodiment, R¹ and R² are linked to form a 3-member ring. In one aspect of this embodiment, R¹ and R² are linked to form a cyclopropyl ring.

In one aspect of this embodiment, R¹ and R² are linked to form a 4-member ring. In one aspect of this embodiment, R¹ and R² are linked to form a cyclobutyl ring.

In one aspect of this embodiment, R¹ and R² are linked to form a 5-member ring. In one aspect of this embodiment, R¹ and R² are linked to form a cyclopentyl ring.

In one aspect of this embodiment, R¹ and R² are linked to form a 6-member ring. In one aspect of this embodiment, R¹ and R² are linked to form a cyclohexyl ring.

In one aspect of this embodiment, three or more of L¹, R¹, R², R³, R⁴, R⁵ and R⁶ are a methyl group (“Me” or “—CH₃”). In one aspect of this embodiment, two or more of L¹, R¹, R², R³, R⁴, R⁵ and R⁶ are a methyl group (“Me” or “—CH₃”). In one aspect of this embodiment, L¹, R¹, R², R³ and R⁴ are each a methyl group (“Me” or “—CH₃”). In one aspect of this embodiment, at least R¹ and R² are each a methyl group (“Me” or “—CH₃”). In one aspect of this embodiment, n=1 and L¹, R¹, R², R³ and R⁴ are each a methyl group (“Me” or “—CH₃”). In one aspect of this embodiment, n=2 and L¹, R¹, R², R³ and R⁴ are each a methyl group (“Me” or “—CH₃”). In one aspect of this embodiment, R⁵ and R⁶ are present and are each a methyl group (“Me” or “—CH₃”).

In one aspect of this embodiment, three of L¹, R¹, R², R³, R⁴, R⁵ and R⁶ are an ethyl group (“Et” or “—CH₂CH₃”). In one aspect of this embodiment, two of L¹, R¹, R², R³, R⁴, R⁵ and R⁶ are an ethyl group (“Et” or “—CH₂CH₃”). In one aspect of this embodiment, each of L¹, R¹, R², R³ and R⁴ are an ethyl group (“Et” or “—CH₂CH₃”). In one aspect of this embodiment, n=1 and L¹, R¹, R², R³ and R⁴ are each an ethyl group (“Et” or “—CH₂CH₃”). In one aspect of this embodiment, n=2 and L¹, R¹, R², R³ and R⁴ are each an ethyl group (“Et” or “—CH₂CH₃”). In one aspect of this embodiment, R⁵ and R⁶ are present and are each an ethyl group (“Et” or “—CH₂CH₃”).

In one aspect of this embodiment, three or more of L¹, R¹, R², R³, R⁴, R⁵ and R⁶ are a propyl group (“Pr” or “—CH₂CH₂CH₃”). In one aspect of this embodiment, two or more of L¹, R¹, R², R³, R⁴, R⁵ and R⁶ are a propyl group (“Pr” or “—CH₂CH₂CH₃”). In one aspect of this embodiment, L¹, R¹, R², R³ and R⁴ are each a propyl group (“Pr” or “—CH₂CH₂CH₃”). In one aspect of this embodiment, n=1 and L¹, R¹, R², R³ and R⁴ are each a propyl group (“Pr” or “—CH₂CH₂CH₃”). In one aspect of this embodiment, n=2 and L¹, R¹, R², R³ and R⁴ are each a propyl group (“Pr” or “—CH₂CH₂CH₃”). In one aspect of this embodiment, R⁵ and R⁶ are present and are each a propyl group (“Pr” or “—CH₂CH₂CH₃”).

In one aspect of this embodiment, two or more of L¹, R¹, R², R³, R⁴, R⁵ and R⁶ are an isopropyl group (“iPr”). In one aspect of this embodiment, at least one of L¹, R¹, R², R³, R⁴, R⁵ and R⁶ is an isopropyl group (“iPr”).

In one embodiment, the Group 13 compounds/precursors have Formula III:

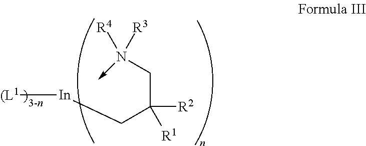

where
(a) R¹ and R² (i) are each independently one of a C₁-C₆ linear alkyl group, a C₃-C₆ branched alkyl group, and a C₃-C₆ cyclic alkyl group or (ii) are linked to form one of a 3-member ring, a 4-member ring, a 5-member ring and a 6-member ring;
(b) R³ and R⁴ are each independently one of a C₁-C₆ linear alkyl group, a C₃-C₆ branched alkyl group and a C₃-C₆ cyclic alkyl group;

$$n = 1 - 3 ; \qquad ( c )$$

(d) L¹ is one of a C₁-C₆ linear alkyl group, a C₃-C₆ branched alkyl group, and an amino group of formula —NR⁵R⁶ where R⁵ and R⁶ are each independently one of a C₁-C₆ linear alkyl group and a C₁-C₆ branched alkyl group.

In one aspect of this embodiment, n=1. In another aspect of this embodiment, n=2. In another aspect of this embodiment, n=3.

In one aspect of this embodiment, R¹ and R² are each independently one of a C₁-C₆ linear alkyl group, a C₃-C₆ branched alkyl group and a C₃-C₆ cyclic alkyl group. In one aspect of this embodiment, R³ and R⁴ are each independently one of a C₁-C₆ linear alkyl group, a C₃-C₆ branched alkyl group and a C₃-C₆ cyclic alkyl group. In one aspect of this embodiment, R¹, R², R³ and R⁴ are each independently one of a C₁-C₆ linear alkyl group, a C₃-C₆ branched alkyl group and a C₃-C₆ cyclic alkyl group.

In one aspect of this embodiment, R^{t} and R² are linked to form one of a 3-member ring, a 4-member ring, a 5-member ring and a 6-member ring.

In one aspect of this embodiment, R¹ and R² are linked to form a 3-member ring. In one aspect of this embodiment, R¹ and R² are linked to form a cyclopropyl ring.

In one aspect of this embodiment, R¹ and R² are linked to form a 4-member ring. In one aspect of this embodiment, R¹ and R² are linked to form a cyclobutyl ring.

In one aspect of this embodiment, R¹ and R² are linked to form a 5-member ring. In one aspect of this embodiment, R¹ and R² are linked to form a cyclopentyl ring.

In one aspect of this embodiment, R¹ and R² are linked to form a 6-member ring. In one aspect of this embodiment, R¹ and R² are linked to form a cyclohexyl ring.

In one aspect of this embodiment, three or more of L¹, R¹, R², R³, R⁴, R⁵ and R⁶ are a methyl group (“Me” or “—CH₃”). In one aspect of this embodiment, two or more of L¹, R¹, R², R³, R⁴, R⁵ and R⁶ are a methyl group (“Me” or “—CH₃”). In one aspect of this embodiment, L¹, R¹, R², R³ and R⁴ are each a methyl group (“Me” or “—CH₃”). In one aspect of this embodiment, at least R¹ and R² are each a methyl group (“Me” or “—CH₃”). In one aspect of this embodiment, n=1 and L¹, R¹, R², R³ and R⁴ are each a methyl group (“Me” or “—CH₃”). In one aspect of this embodiment, n=2 and L¹, R¹, R², R³ and R⁴ are each a methyl group (“Me” or “—CH₃”). In one aspect of this embodiment, R⁵ and R⁶ are present and are each a methyl group (“Me” or “—CH₃”).

In one aspect of this embodiment, three of L¹, R¹, R², R³, R⁴, R⁵ and R⁶ are an ethyl group (“Et” or “—CH₂CH₃”). In one aspect of this embodiment, two of L¹, R¹, R², R³, R⁴, R⁵ and R⁶ are an ethyl group (“Et” or “—CH₂CH₃”). In one aspect of this embodiment, L¹, R¹, R², R³ and R⁴ are each an ethyl group (“Et” or “—CH₂CH₃”). In one aspect of this embodiment, n=1 and L¹, R¹, R², R³ and R⁴ are each an ethyl group (“Et” or “—CH₂CH₃”). In one aspect of this embodiment, n=2 and L¹, R¹, R², R³ and R⁴ are each an ethyl group (“Et” or “—CH₂CH₃”). In one aspect of this embodiment, R⁵ and R⁶ are present and are each an ethyl group (“Et” or “—CH₂CH₃”).

In one aspect of this embodiment, three or more of L¹, R¹, R², R³, R⁴, R⁵ and R⁶ are a propyl group (“Pr” or “—CH₂CH₂CH₃”). In one aspect of this embodiment, two or more of L¹, R¹, R², R³, R⁴, R⁵ and R⁶ are a propyl group (“Pr” or “—CH₂CH₂CH₃”). In one aspect of this embodiment, L¹, R¹, R², R³ and R⁴ are each a propyl group (“Pr” or “—CH₂CH₂CH₃”). In one aspect of this embodiment, n=1 and L¹, R¹, R², R³ and R⁴ are each a propyl group (“Pr” or “—CH₂CH₂CH₃”). In one aspect of this embodiment, n=2 and L¹, R¹, R², R³ and R⁴ are each a propyl group (“Pr” or “—CH₂CH₂CH₃”). In one aspect of this embodiment, R⁵ and R⁶ are present and are each a propyl group (“Pr” or “—CH₂CH₂CH₃”).

In one aspect of this embodiment, two or more of L¹, R¹, R², R³, R⁴, R⁵ and R⁶ are an isopropyl group (“iPr”). In one aspect of this embodiment, at least one of L¹, R¹, R², R³, R⁴, R⁵ and R⁶ is an isopropyl group (“iPr”).

### Specific Exemplary Embodiments

In one embodiment, M=In, n=1, L=Me and each of R¹, R², R³ and R⁴=Me as follows:

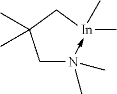

In one embodiment, M=In, n=2, L¹=Me and each of R¹, R², R³ and R⁴=Me as follows:

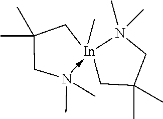

In one embodiment, M=Ga, n=1, L¹=Me and each of R¹, R², R³ and R⁴=Me as follows:

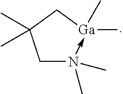

In one embodiment, M=Ga, n=2, L¹=Me and each of R¹, R², R³ and R⁴=Me as follows:

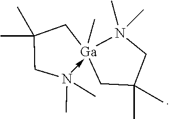

In one embodiment, M=Al, n=1, L¹=Me and each of R¹, R², R³ and R⁴=Me as follows:

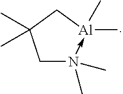

In one embodiment, M=Al, n=2, L¹=Me and each of R¹, R², R³ and R⁴=Me as follows:

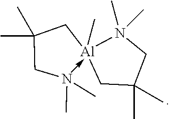

In one embodiment, M=In, n=1, L¹=—NR⁵R⁶ where R⁵ and R⁶=Et and each of R¹, R², R³ and R⁴=Me as follows:

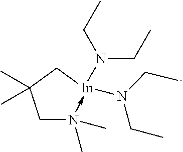

In one embodiment, M=Al, n=1, L¹=—NR⁵R⁶ where R⁵ and R⁶=Et and each of R¹, R², R³ and R⁴=Me as follows:

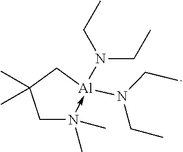

In one embodiment, M=Ga, n=1, L¹=—NR⁵R⁶ where R⁵ and R⁶=Et and each of R¹, R², R³ and R⁴=Me as follows:

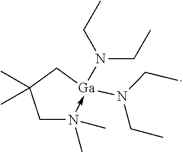

In one embodiment, M=In, n=1, L¹=Me, each of R¹, R² and R³=Me and R⁴=Et as follows:

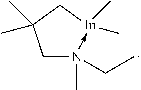

In one embodiment, M=In, n=1, L¹=Me, R¹ and R² are linked to form a cyclopropyl group (“^{cy}Pr”) and each of R³ and R⁴=Me as follows:

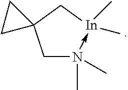

In one embodiment, M=In, n=1, L1=Me, R1 and R2 are linked to form a cyclopentyl group (“cyPent”) and each of R3 and R4=Me as follows:

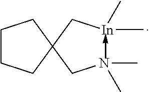

### Method of Use

The disclosed precursors may be deposited to form lanthanide-containing films using any chemical vapor deposition process known to those of skill in the art. As used herein, the term “chemical vapor deposition process” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous,” it is understood that the precursors can be either liquid or solid which are transported with or without an inert gas into the reactor via direct vaporization, bubbling or sublimation. In some case, the vaporized precursors can pass through a plasma generator. The term “reactor” as used herein, includes without limitation, reaction chamber, reaction vessel or deposition chamber.

Chemical vapor deposition processes in which the disclosed and claimed precursors can be utilized include, but are not limited to, those used for the manufacture of semiconductor type microelectronic devices such as ALD, CVD, pulsed CVD, plasma enhanced ALD (PEALD) and/or plasma enhanced CVD (PECVD). Examples of suitable deposition processes for the method disclosed herein include, but are not limited to, cyclic CVD (CCVD), MOCVD (Metal Organic CVD), thermal chemical vapor deposition, plasma enhanced chemical vapor deposition (“PECVD”), high density PECVD, photon assisted CVD, plasma-photon assisted (“PPECVD”), cryogenic chemical vapor deposition, chemical assisted vapor deposition, hot-filament chemical vapor deposition, CVD of a liquid polymer precursor, deposition from supercritical fluids, and low energy CVD (LECVD). In certain embodiments, the metal containing films are deposited via atomic layer deposition (ALD), plasma enhanced ALD (PEALD) or plasma enhanced cyclic CVD (PECCVD) process.

In one embodiment, for example, the metal-containing film is deposited using an ALD process. In another embodiment, the metal-containing film is deposited using a CCVD process. In a further embodiment, the metal-containing film is deposited using a thermal CVD process.

Suitable substrates on which the disclosed and claimed precursors can be deposited are not particularly limited and vary depending on the final use intended. For example, the substrate may be chosen from oxides such as HfO₂ based materials, TiO₂ based materials, ZrO₂ based materials, rare earth oxide-based materials, ternary oxide-based materials, etc. or from nitride-based films. Other substrates may include solid substrates such as metal substrates (for example, Au, Pd, Rh, Ru, W, Al, Ni, Ti, Co, Pt and metal silicides (e.g., TiSi₂, CoSi₂, and NiSi₂); metal nitride containing substrates (e.g., TaN, TiN, WN, TaCN, TiCN, TaSiN, and TiSiN), semiconductor materials (e.g., Si, SiGe, GaAs, InP, diamond, GaN, and SiC); insulators (e.g., SiO₂, Si₃N₄, SiON, HfO₂, Ta₂O₅, ZrO₂, TiO₂, Al₂O₃, and barium strontium titanate); combinations thereof. Preferred substrates include TiN, Ru and Si type substrates.

In such deposition methods and processes an oxidizing agent can be utilized. The oxidizing agent is typically introduced in gaseous form. Examples of suitable oxidizing agents include, but are not limited to, oxygen gas, water vapor, ozone, oxygen plasma, or mixtures thereof.

The deposition methods and processes may also involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, and mixtures thereof. For example, a purge gas such as Ar is supplied into the reactor at a flow rate ranging from about 10 to about 2000 sccm for about 0.1 to 10000 seconds, thereby purging the unreacted material and any byproduct that may remain in the reactor.

The deposition methods and processes require that energy be applied to the at least one of the precursors, oxidizing agent, other precursors or combination thereof to induce reaction and to form the metal-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In some processes, a secondary RF frequency source can be used to modify the plasma characteristics at the substrate surface. When utilizing plasma, the plasma-generated process may include a direct plasma-generated process in which plasma is directly generated in the reactor, or alternatively a remote plasma-generated process in which plasma is generated outside of the reactor and supplied into the reactor.

When utilized in such deposition methods and processes suitable precursors—such as those presently disclosed and claimed—may be delivered to the reaction chamber such as a CVD or ALD reactor in a variety of ways. In some instances, a liquid delivery system may be utilized. In other instances, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. The precursor compositions described herein can be effectively used as source reagents via direct liquid injection (DLI) to provide a vapor stream of these metal precursors into an ALD or CVD reactor.

When used in these deposition methods and processes, the disclosed and claimed precursors include hydrocarbon solvents which are particularly desirable due to their ability to be dried to sub-ppm levels of water. Exemplary hydrocarbon solvents that can be used in the precursors include, but are not limited to, toluene, mesitylene, cumene (isopropylbenzene), p-cymene (4-isopropyl toluene), 1,3-diisopropylbenzene, octane, dodecane, 1,2,4-trimethylcyclohexane, n-butylcyclohexane, and decahydronaphthalene (decalin). The disclosed and claimed precursors can also be stored and used in stainless steel containers. In certain embodiments, the hydrocarbon solvent is a high boiling point solvent or has a boiling point of 100 degrees Celsius or greater. The disclosed and claimed precursors can also be mixed with other suitable metal precursors, and the mixture used to deliver both metals simultaneously for the growth of a binary metal-containing films.

A flow of argon and/or other gas may be employed as a carrier gas to help deliver a vapor containing at least one of the disclosed and claimed precursors to the reaction chamber during the precursor pulsing. When delivering the precursors, the reaction chamber process pressure is between 1 and 50 torr, preferably between 5 and 20 torr.

Substrate temperature can be an important process variable in the deposition of high-quality metal-containing films. Typical substrate temperatures range from about 150° C. to about 550° C. Higher temperatures can promote higher film growth rates.

In view of the forgoing, those skilled in the art will recognize that the disclosed and claimed subject matter further include the use of the disclosed and claimed precursors in Chemical vapor deposition processes as follows.

In one embodiment, the disclosed and claimed subject matter includes a method for forming a Group 13 metal-containing film on at least one surface of a substrate that includes the steps of:
a. providing the at least one surface of the substrate in a reaction vessel;
b. forming a Group 13 metal-containing film on the at least one surface by a deposition process chosen from a chemical vapor deposition (CVD) process and an atomic layer deposition (ALD) process using one of the disclosed and claimed precursors as a metal source compound for the deposition process.
   In a further aspect of this embodiment, the method includes introducing at least one reactant into the reaction vessel. In a further aspect of this embodiment, the method includes introducing at least one reactant into the reaction vessel where the at least one reactant is selected from the group of water, diatomic oxygen, oxygen plasma, ozone, NO, N₂O, NO₂, carbon monoxide, carbon dioxide and combinations thereof. In another aspect of this embodiment, the method includes introducing at least one reactant into the reaction vessel where the at least one reactant is selected from the group of ammonia, hydrazine, monoalkylhydrazine, dialkylhydrazine, nitrogen, nitrogen/hydrogen, ammonia plasma, nitrogen plasma, nitrogen/hydrogen plasma, and combinations thereof. In another aspect of this embodiment, the method includes introducing at least one reactant into the reaction vessel where the at least one reactant is selected from the group hydrogen, hydrogen plasma, a mixture of hydrogen and helium, a mixture of hydrogen and argon, hydrogen/helium plasma, hydrogen/argon plasma, boron-containing compounds, silicon-containing compounds and combinations thereof.

In one embodiment, the disclosed and claimed subject matter includes a method of forming a Group 13 metal-containing film via an atomic layer deposition (ALD) process or ALD-like process that includes the steps of.
a. providing a substrate in a reaction vessel;
b. introducing into the reaction vessel one or more of the disclosed and claimed precursors;
c. purging the reaction vessel with a first purge gas;
d. introducing into the reaction vessel a source gas;
e. purging the reaction vessel with a second purge gas;
f. sequentially repeating steps b through e until a desired thickness of the Group 13 metal-containing film is obtained.
   In a further aspect of this embodiment, the source gas is one or more of an oxygen-containing source gas selected from water, diatomic oxygen, oxygen plasma, ozone, NO, N₂O, NO₂, carbon monoxide, carbon dioxide and combinations thereof. In another aspect of this embodiment, the source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof. In a further aspect of this embodiment, the first and second purge gases are each independently selected one or more of argon, nitrogen, helium, neon, and combinations thereof. In a further aspect of this embodiment, the method further includes applying energy to at least one of the precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma methods and combinations thereof. In a further aspect of this embodiment, step b of the method further includes introducing into the reaction vessel the precursor using a stream of carrier gas to deliver a vapor of the precursor into the reaction vessel. In a further aspect of this embodiment, step b of the method further includes use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

All solvents and starting materials were purchased from Sigma-Aldrich unless otherwise indicated.

### Example 1

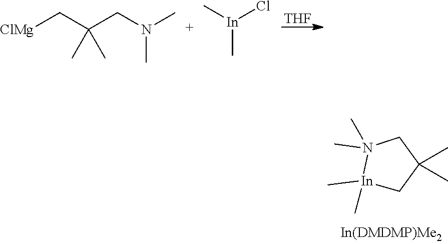

Dimethyl-indium-chloride (1 eq.) was dissolved in dry THF. The solution was cooled to 0° C. and 1 eq. of a Grignard solution, prepared from 3-(N,N-dimethylamino)-2,2-dimethyl-1-propylchloride and Mg turnings, was added dropwise. The mixture was allowed to warm up to room temperature and was stirred overnight. The solvent was removed from the mixture under reduced pressure and the crude leftover was suspended in 50 mL pentane. After 1 hour of stirring, the suspension was filtered. From the filtrate the solvent was removed under reduced pressure and the crude product was distilled and collected (oil bath at 50° C., 20 cm column, 2×10⁻² mbar, cooled collection flask; 60% yield).

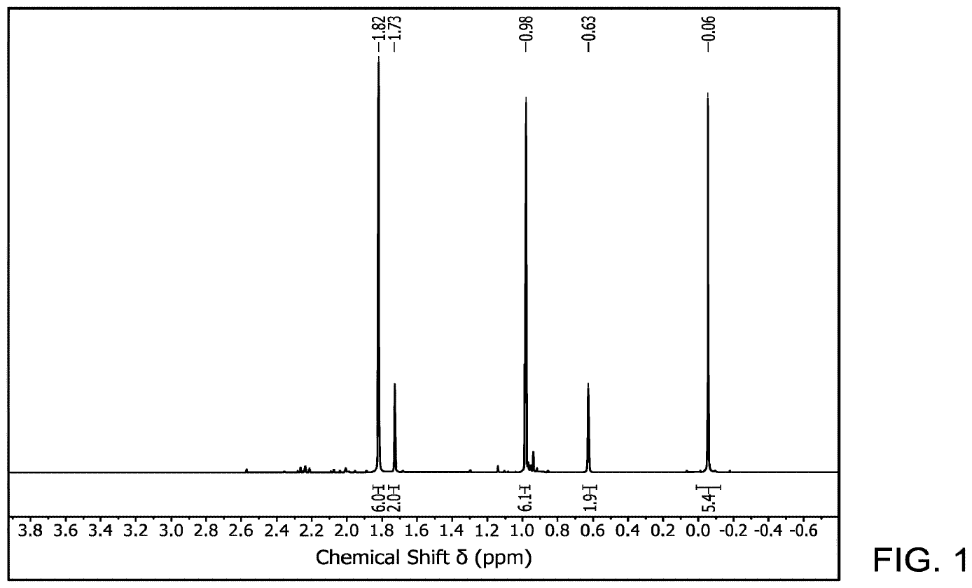

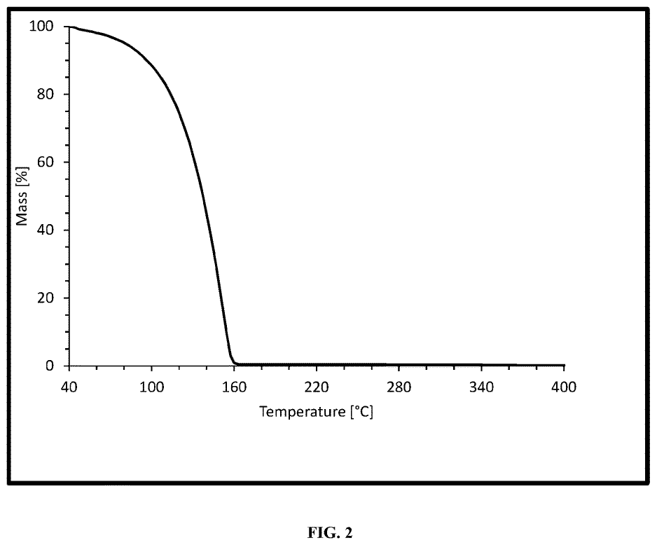

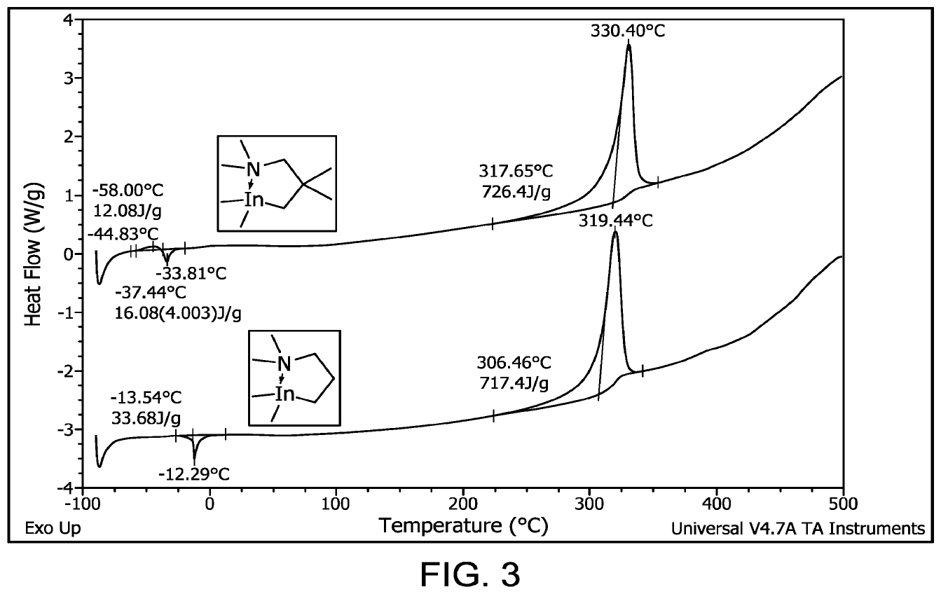

Characterization of In(DMDMP)Me₂: ¹H NMR (500 MHz, C₆D₆) δ 1.82 (s, 6H), 1.73 (s, 1H), 0.98 (s, 6H), 0.63 (s, 2H), −0.06 (s, 6H), see FIG. 1; TGA: T_{50%}=137° C., see FIG. 2; DSC: Melting point −34° C.; DSC decomposition temperature 330.4° C., see FIG. 3.

### Example 2

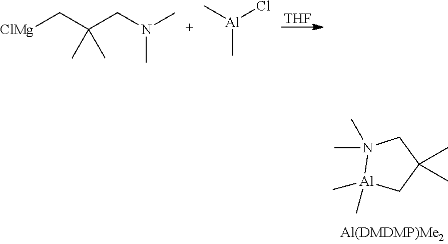

Dimethyl-aluminum-chloride (1 eq.) was dissolved in dry THF. The solution was cooled to 0° C. and 1 eq. of a Grignard solution, prepared from 3-(N,N-dimethylamino)-2,2-dimethyl-1-propylchloride and Mg turnings, was added dropwise. The mixture was allowed to warm up to room temperature and was stirred overnight. The solvent was removed from the mixture under reduced pressure and the crude leftover was suspended in 50 mL pentane. After 1 night of stirring, the suspension was filtered. From the filtrate the solvent was removed under reduced pressure and the crude liquid product was distilled and collected (oil bath at 25° C., 2×10⁻² mbar, cooled collection flask; 60% yield).

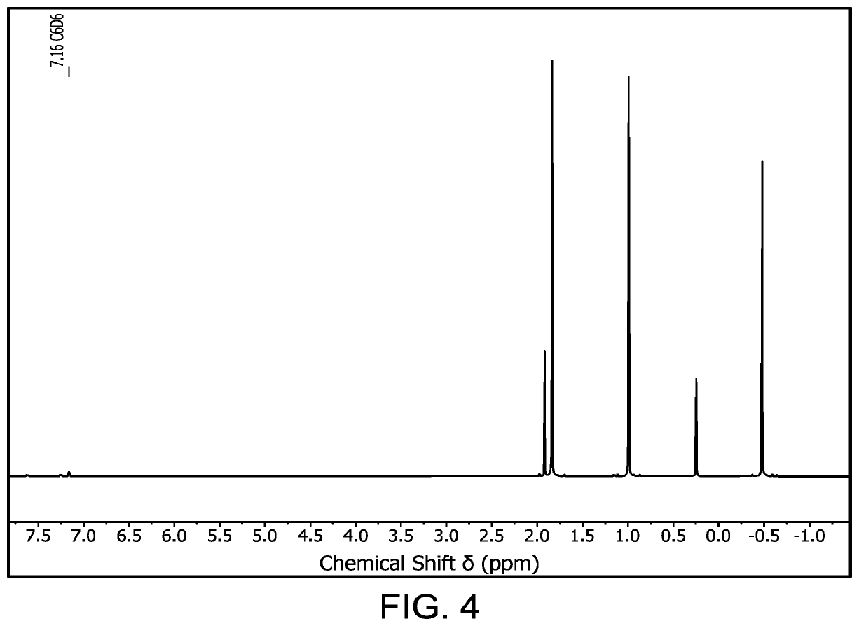

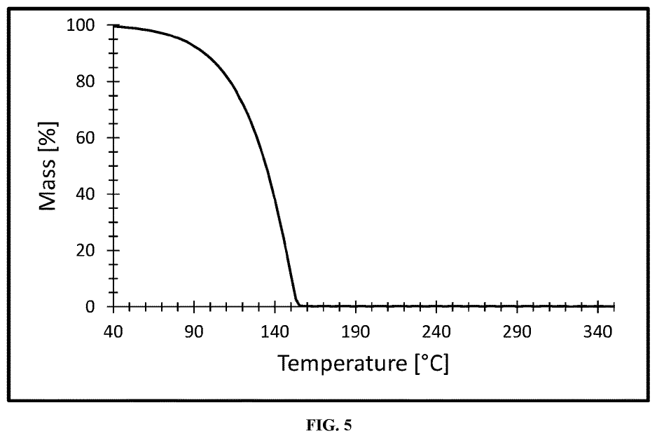

Characterization of Al(DMDMP)Me₂: ¹H NMR (500 MHz, C₆D₆) δ 1.92 (s, 2H), 1.84 (s, 6H), 0.99 (s, 6H), 0.25 (s, 2H), −0.48 (s, 6H), see FIG. 4. TGA: T_{50%}=135° C., see FIG. 5; DSC: Decomposition temperature 415° C.

### Example 3

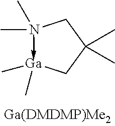

Gallium trichloride (1 eq.) was dissolved in dry THF. The solution was cooled to 0° C. and 1 eq. of a Grignard solution, prepared from 3-(N,N-dimethylamino)-2,2-dimethyl-1-propylchloride and Mg turnings, was added dropwise. Then, 2 eq. of a methyllithium solution (1.6 M in diethyl ether) was added dropwise. The mixture was allowed to warm up to room temperature and was stirred overnight. The solvent was removed from the mixture under reduced pressure and the crude leftover was suspended in 50 mL pentane. After 1 night of stirring, the suspension was filtered. From the filtrate the solvent was removed under reduced pressure and the crude liquid product was distilled and collected (oil bath at 25° C., 7×10³ mbar, cooled collection flask; 30% yield).

Characterization of Ga(DMDMP)Me₂: ¹H NMR (500 MHz, C₆D₆) δ 1.86 (s, 6H), 1.83 (s, 2H), 0.98 (s, 6H), 0.52 (s, 2H), −0.14 (s, 6H), TGA: T₅₀=125° C.; DSC: Melting point −27° C., decomposition temperature 417° C.

### Example 4

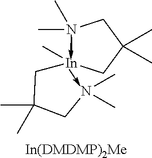

Indium trichloride (1 eq.) was dissolved in dry THF. The solution was cooled to 0° C. and 2 eq. of a Grignard solution, prepared from 3-(N,N-dimethylamino)-2,2-dimethyl-1-propylchloride and Mg turnings, was added dropwise. Then, 1 eq. of a methyllithium solution (1.6 M in diethyl ether) was added dropwise. The mixture was allowed to warm up to room temperature and was stirred overnight. The solvent was removed from the mixture under reduced pressure and the crude leftover was suspended in 50 mL pentane. After 1 night of stirring, the suspension was filtered. From the filtrate the solvent was removed under reduced pressure and the crude product was sublimed and collected (oil bath at 60° C., 2×10⁻² mbar, cooled collection flask; 80% yield).

Characterization of In(DMDMP)₂Me: ¹H NMR (500 MHz, C₆D₆) δ 2.01 (s, 12H), 1.89 (s, 4H), 1.14 (s, 12H), 0.57 (s, 4H), −0.02 (s, 3H), TGA: T_{50%}=190° C.; DSC: Melting point 57° C., decomposition temperature 316° C.

### Example 5

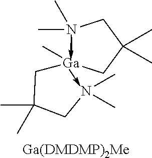

Gallium trichloride (1 eq.) was dissolved in dry THF. The solution was cooled to 0° C. and 2 eq. of a Grignard solution, prepared from 3-(N,N-dimethylamino)-2,2-dimethyl-1-propylchloride and Mg turnings, was added dropwise. Then, 1 eq. of a methyllithium solution (1.6 M in diethyl ether) was added dropwise. The mixture was allowed to warm up to room temperature and was stirred overnight. The solvent was removed from the mixture under reduced pressure and the crude leftover was suspended in 50 mL pentane. After 1 night of stirring, the suspension was filtered. From the filtrate the solvent was removed under reduced pressure and the crude liquid product was distilled and collected (oil bath at 60° C., 4×10⁻³ mbar, cooled collection flask; 55% yield).

Characterization of Ga(DMDMP)₂Me: ¹H NMR (500 MHz, C₆D₆) δ 2.03 (s, 12H), 1.96 (m, 4H), 1.13 (s, 12H), 0.50 (m, 4H), −0.06 (s, 3H), TGA: T_{50%}=175° C.; DSC: Melting point 24° C., decomposition temperature 390° C.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. A precursor having Formula I: 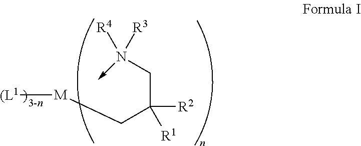
wherein
(a) R¹ and R² (i) are each independently one of a C₁-C₆ linear alkyl group, a C₃-C₆ branched alkyl group and a C₃-C₆ cyclic alkyl group or (ii) are linked to form one of a 3-member ring, a 4-member ring, a 5-member ring and a 6-member ring;
(b) R³ and R⁴ are each independently one of a C₁-C₆ linear alkyl group, a C₃-C₆ branched alkyl group and a C₃-C₆ cyclic alkyl group;
$$n = 1 - 3 ; \qquad ( c )$$
(d) M is one of B, Al, Ga and In; and
(e) L¹ is one of a C₁-C₆ linear alkyl group, a C₃-C₆ branched alkyl group and an amino group of formula —NR⁵R⁶ wherein R⁵ and R⁶ are each independently one of a C₁-C₆ linear alkyl group and a C₃-C₆ branched alkyl group.

2. (canceled)

3. (canceled)

4. The precursor of claim 1, wherein M is B.

5. The precursor of claim 1, wherein M is Al.

6. The precursor of claim 1, wherein M is Ga.

7. The precursor of claim 1, wherein M is In.

8. The precursor of claim 1, wherein n=1.

9. The precursor of claim 1, wherein n=2.

10. The precursor of claim 1, wherein n=3.

11-39. (canceled)

40. The precursor of claim 1, wherein M=In, n=1, L¹=Me and each of R¹, R², R³ and R⁴=Me.

41. The precursor of claim 1, wherein M=In, n=2, L¹=Me and each of R¹, R², R³ and R⁴=Me.

42. The precursor of claim 1, wherein M=Ga, n=1, L¹=Me and each of R¹, R², R³ and R⁴=Me.

43. The precursor of claim 1, wherein M=Ga, n=2, L¹=Me and each of R¹, R², R³ and R⁴=Me.

44. The precursor of claim 1, wherein M=Al, n=1, L¹=Me and each of R¹, R², R³ and R⁴=Me.

45. The precursor of claim 1, wherein M=Al, n=2, L¹=Me and each of R¹, R², R³ and R⁴=Me.

46. The precursor of claim 1, wherein M=In, n=1, L¹=—NR⁵R⁶ where R⁵ and R⁶=Et and each of R¹, R², R³ and R⁴=Me.

47. The precursor of claim 1, wherein M=Al, n=1, L¹=—NR⁵R⁶ where R⁵ and R⁶=Et and each of R¹, R², R³ and R⁴=Me.

48. The precursor of claim 1, wherein M=Ga, n=1, L¹=—NR⁵R⁶ where R⁵ and R⁶=Et and each of R¹, R², R³ and R⁴=Me.

49. The precursor of claim 1, wherein M=In, n=1, L¹=Me, each of R¹, R² and R³=Me and R⁴=Et.

50. The precursor of claim 1, wherein M=In, n=1, L¹=Me, R¹ and R² are linked to form a cyclopropyl group (“^{cy}Pr”) and each of R³ and R⁴=Me.

51. The precursor of claim 1, wherein M=In, n=1, L¹=Me, R¹ and R² are linked to form a cyclopentyl group (“^{cy}Pent”) and each of R³ and R⁴=Me.

52. A method for forming a Group 13 metal-containing film on at least one surface of a substrate comprising:
a. providing the at least one surface of the substrate in a reaction vessel;
b. forming a Group 13 metal-containing film on the at least one surface by a deposition process chosen from a chemical vapor deposition (CVD) process and an atomic layer deposition (ALD) process using the precursor of claim 1 as a metal source compound for the deposition process.

53-64. (canceled)

65. A precursor supply package, comprising a vessel and the precursor of claim 1, wherein the vessel is adapted to contain and dispense the precursor.
